(19) United States
(12) Patent Application Publication
(10) Pub. No.: US 2026/0153547 A1
(43) Pub. Date: Jun. 4, 2026

(54) MODE STIRRER AND ELECTROMAGNETIC REVERBERATION CHAMBER INCLUDING MODE STIRRER

(71) Applicant: ELECTRONICS AND TELECOMMUNICATIONS RESEARCH INSTITUTE, Daejeon (KR)

(72) Inventors: Dong-Uk SIM, Daejeon (KR); Jung Ick MOON, Daejeon (KR)

(73) Assignee: ELECTRONICS AND TELECOMMUNICATIONS RESEARCH INSTITUTE, Daejeon (KR)

(21) Appl. No.: 19/215,106

(22) Filed: May 21, 2025

(30) Foreign Application Priority Data
Oct. 22, 2024 (KR) 10-2024-0144676

(51) Int. Cl. G01R 29/08

(52) U.S. Cl. CPC G01R 29/0821; G01R 29/0871

(57) ABSTRACT

A mode stirrer and an electromagnetic reverberation chamber including the mode stirrer are provided. The mode stirrer installed in an electromagnetic reverberation chamber includes a mode stirring panel configured to be rotated on a traverse section by a motor and a vertical movement portion configured to change a height of the mode stirring panel according to the rotating of the mode stirring panel and move the mode stirring panel up and down.

### CROSS-REFERENCE TO RELATED APPLICATION

This application claims the benefit of Korean Patent Application No. 10-2024-0144676, filed on Oct. 22, 2024, in the Korean Intellectual Property Office, the entire disclosure of which is incorporated herein by reference for all purposes.

### BACKGROUND

### 1. Field of the Invention

One or more embodiments relate to a mode stirrer and an electromagnetic reverberation chamber including the mode stirrer. Specifically, the present disclosure relates to a mode stirrer with improved motion and an electromagnetic reverberation chamber including the mode stirrer and having improved field uniformity performance.

### 2. Description of the Related Art

An electromagnetic reverberation chamber is in the spotlight as an alternative facility for electromagnetic compatibility (EMC) testing. A core element of the electromagnetic reverberation chamber is a mode stirrer.

The design of the mode stirrer has two aspects. The first is a design for a mode stirrer structure that may satisfy a field uniformity performance standard, and the second is a design for dynamic stirring of the mode stirrer structure.

In other words, a mode stirrer for achieving target performance by improving uniformity performance using one of the design for the mode stirrer structure or the design for the dynamic stirring is requested.

### SUMMARY

Embodiments provide an electromagnetic reverberation chamber with improved field uniformity performance by reducing measurement uncertainty in electromagnetic compatibility (EMC) measurement and over-the-air (OTA) performance evaluation of a wireless terminal, by having a mode stirrer for performing up-and-down movement together with horizontal rotation.

According to an aspect, there is provided a mode stirrer including a mode stirring panel configured to be rotated on a traverse section by a motor and a vertical movement portion configured to change a height of the mode stirring panel according to the rotating of the mode stirring panel and move the mode stirring panel up and down.

The vertical movement portion may include a diagonal cut pipe in which an upper portion is coupled to a ceiling of the electromagnetic reverberation chamber and a lower portion is diagonally cut to form a cylindrical shape with different heights and a vertical column in which a lower portion is coupled to an upper portion of the mode stirring panel and an upper portion is in contact with the lower portion of the diagonal cut pipe, wherein the vertical column may be configured to, when the mode stirring panel rotates, change the height of the mode stirring panel by moving up and down along a diagonal line formed at the lower portion of the diagonal cut pipe.

The vertical movement portion may further include a position restoration portion configured to be coupled between a lower portion of the mode stirring panel and a floor of the electromagnetic reverberation chamber, when the vertical column moves downward along the diagonal line formed at the lower portion of the diagonal cut pipe, contract by pressure being applied from the mode stirring panel that is coupled to the vertical column and moving downward, and when the vertical column moves upward along the diagonal line formed at the lower portion of the diagonal cut pipe and pressure from the mode stirring panel decreases, be tensioned and push the mode stirring panel upward.

The vertical movement portion may include a diagonal cut pipe in which a lower portion is coupled to a floor of the electromagnetic reverberation chamber and an upper portion is diagonally cut to form a cylindrical shape with different heights and a vertical column in which an upper portion is coupled to a lower portion of the mode stirring panel and a lower portion is in contact with the upper portion of the diagonal cut pipe, wherein the vertical column may be configured to, when the mode stirring panel rotates, change the height of the mode stirring panel by moving up and down along a diagonal line formed at the upper portion of the diagonal cut pipe.

The vertical movement portion may further include a position restoration portion configured to be coupled between an upper portion of the mode stirring panel and a ceiling of the electromagnetic reverberation chamber, when the vertical column moves upward along the diagonal line formed at the upper portion of the diagonal cut pipe, contract by pressure being applied from the mode stirring panel that is coupled to the vertical column and moving upward and downward, and when the vertical column moves downward along the diagonal line formed at the upper portion of the diagonal cut pipe and pressure from the mode stirring panel decreases, be tensioned and push the mode stirring panel downward.

According to an aspect, there is provided an electromagnetic reverberation chamber including a transmission antenna configured to output a wireless signal for measuring wireless performance, a mode stirrer including a mode stirring panel, a motor configured to rotate the mode stirring panel on a traverse section, and a reception electric field probe configured to receive a reflection signal generated by a wireless signal output from the transmission antenna being reflected by the mode stirring panel, wherein the mode stirrer may include a vertical movement portion configured to change a height of the mode stirring panel according to the rotating of the mode stirring panel and move the mode stirring panel up and down.

The vertical movement portion may include a diagonal cut pipe in which an upper portion is coupled to a ceiling of the electromagnetic reverberation chamber and a lower portion is diagonally cut to form a cylindrical shape with different heights and a vertical column in which a lower portion is coupled to an upper portion of the mode stirring panel and an upper portion is in contact with the lower portion of the diagonal cut pipe, wherein the vertical column may be configured to, when the mode stirring panel rotates, change the height of the mode stirring panel by moving up and down along a diagonal line formed at the lower portion of the diagonal cut pipe.

The vertical movement portion may further include a position restoration portion configured to be coupled between a lower portion of the mode stirring panel and a floor of the electromagnetic reverberation chamber, when the vertical column moves downward along the diagonal line formed at the lower portion of the diagonal cut pipe, contract by pressure being applied from the mode stirring panel that is coupled to the vertical column and moving downward, and when the vertical column moves upward along the diagonal line formed at the lower portion of the diagonal cut pipe and pressure from the mode stirring panel decreases, be tensioned and push the mode stirring panel upward.

The vertical movement portion may include a diagonal cut pipe in which a lower portion is coupled to a floor of the electromagnetic reverberation chamber and an upper portion is diagonally cut to form a cylindrical shape with different heights and a vertical column in which an upper portion is coupled to a lower portion of the mode stirring panel and a lower portion is in contact with the upper portion of the diagonal cut pipe, wherein the vertical column may be configured to, when the mode stirring panel rotates, change the height of the mode stirring panel by moving up and down along a diagonal line formed at the upper portion of the diagonal cut pipe.

The vertical movement portion may further include a position restoration portion configured to be coupled between an upper portion of the mode stirring panel and a ceiling of the electromagnetic reverberation chamber, when the vertical column moves upward along the diagonal line formed at the upper portion of the diagonal cut pipe, contract by pressure being applied from the mode stirring panel that is coupled to the vertical column and moving upward and downward, and when the vertical column moves downward along the diagonal line formed at the upper portion of the diagonal cut pipe and pressure from the mode stirring panel decreases, be tensioned and push the mode stirring panel downward.

Additional aspects of embodiments will be set forth in part in the description which follows and, in part, will be apparent from the description, or may be learned by practice of the disclosure.

According to embodiments, an electromagnetic reverberation chamber with improved field uniformity performance by reducing measurement uncertainty in EMC measurement and OTA performance evaluation of a wireless terminal may be provided by having a mode stirrer for performing up-and-down movement together with horizontal rotation.

### BRIEF DESCRIPTION OF THE DRAWINGS

These and/or other aspects, features, and advantages of the invention will become apparent and more readily appreciated from the following description of embodiments, taken in conjunction with the accompanying drawings of which:

FIG. 1 is a plan view of an electromagnetic reverberation chamber including a mode stirrer, according to an embodiment;

FIG. 2 is a front view of an electromagnetic reverberation chamber including a mode stirrer, according to an embodiment;

FIG. 3 is a three-dimensional structure diagram illustrating an electromagnetic reverberation chamber including a mode stirrer, according to an embodiment;

FIG. 4 is an enlarged view of an upper portion of a mode stirrer, according to an embodiment;

FIG. 5 is an enlarged view of a lower portion of a mode stirrer, according to an embodiment;

FIG. 6 illustrates an example of an operation of a mode stirrer, according to an embodiment; and

FIG. 7 illustrates an example of an operation of a mode stirrer upper end central axis according to an operation of the mode stirrer, according to an embodiment.

### DETAILED DESCRIPTION

Hereinafter, embodiments are described in detail with reference to the accompanying drawings.

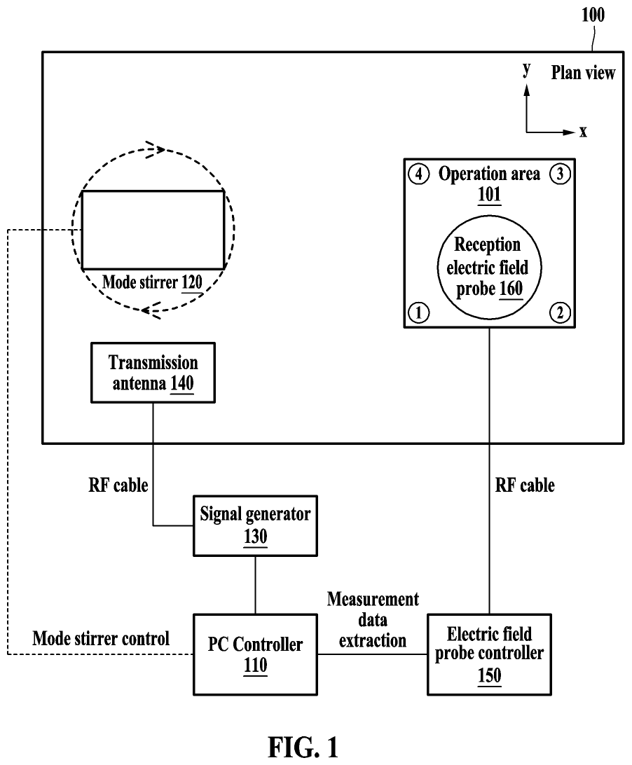

FIG. 1 is a plan view of an electromagnetic reverberation chamber including a mode stirrer, according to an embodiment.

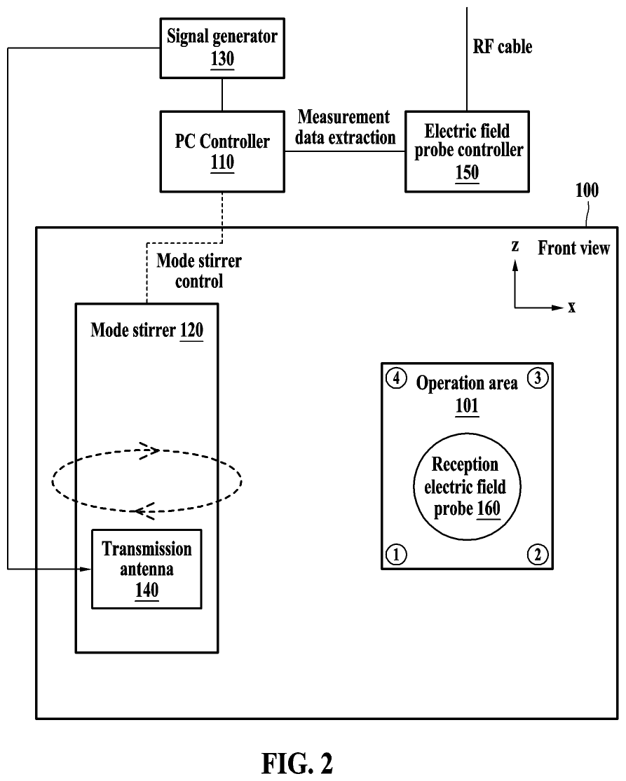

According to an embodiment, an electromagnetic reverberation chamber 100 including a mode stirrer may include a personal computer (PC) controller 110, a mode stirrer 120, a signal generator 130, a transmission antenna 140, an electric field probe controller 150, and a reception electric field probe 160, as shown in FIGS. 1 and 2.

The PC controller 110 may control the mode stirrer 120, the signal generator 130, and the electric field probe controller 150. For example, the PC controller 110 may be one of a PC, a server, or a processor for controlling an electromagnetic reverberation chamber.

The mode stirrer 120 may include a mode stirrer panel formed in a zigzag shape and may operate in a continuous rotation or step-wise rotation manner according to a control of the PC controller 110. The mode stirrer 120 may include a configuration for moving up and down during horizontal rotation.

The signal generator 130 may generate a signal of a frequency band for measuring wireless performance of a wireless terminal according to the control of the PC controller 110. For example, the signal generator 130 may generate a signal for over-the-air (OTA) performance evaluation.

The transmission antenna 140 may be installed inside the electromagnetic reverberation chamber 100, as shown in FIGS. 1 and 2, and may radiate the signal generated by the signal generator 130 into the electromagnetic reverberation chamber 100.

By measuring electric field components at each vertex of an working volume 101 while the mode stirrer 120 is operating, the reception electric field probe 160 may receive a reflection signal generated by a wireless signal output from the transmission antenna 140 being reflected by the mode stirring panel of the mode stirrer 120. The working volume 101 may be a space where the wireless terminal is located to evaluate OTA performance using the electromagnetic reverberation chamber 100.

When the PC controller 110 starts the operation of the mode stirrer 120, the PC controller 110 may request the electric field probe controller 150 to operate the reception electric field probe 160. Here, the electric field probe controller 150 may operate the reception electric field probe 160 according to the request of the PC controller 110. When the PC controller 110 terminates the operation of the mode stirrer 120, the PC controller 110 may request the electric field probe controller 150 to stop the reception electric field probe 160. Here, the electric field probe controller 150 may stop the reception electric field probe 160 according to the request of the PC controller 110.

In addition, the electric field probe controller 150 may receive, from the reception electric field probe 160, the electric field components measured by the reception electric field probe 160 and transmit them to the PC controller 110.

The PC controller 110 may perform a post-processing process on the electric field components received from the electric field probe controller 150 to evaluate the OTA performance of the wireless terminal located inside the working volume 101. Field uniformity performance of an electromagnetic reverberation chamber may be defined as a value obtained by calculating each standard deviation for x, y, z, and total components from electric field intensity measured at each vertex of the working volume while the mode stirrer 120 rotates. Accordingly, when the PC controller 110 performs the post-processing process and the standard deviation for each of the electric field components received from the electric field probe controller 150 corresponds to a standard specification, the PC controller 110 may determine that the OTA performance of the wireless terminal located inside the working volume 101 satisfies the standard specification. For example, when the standard deviation for each of the electric field components received from the electric field probe controller 150 is 3 decibel (dB) or less, the PC controller 110 may determine that the OTA performance of the wireless terminal located inside the working volume 101 satisfies the standard specification.

The present disclosure provides an electromagnetic reverberation chamber with improved field uniformity performance by reducing measurement uncertainty in electromagnetic compatibility (EMC) measurement and OTA performance evaluation of a wireless terminal, by having a mode stirrer for performing up-and-down movement together with horizontal rotation.

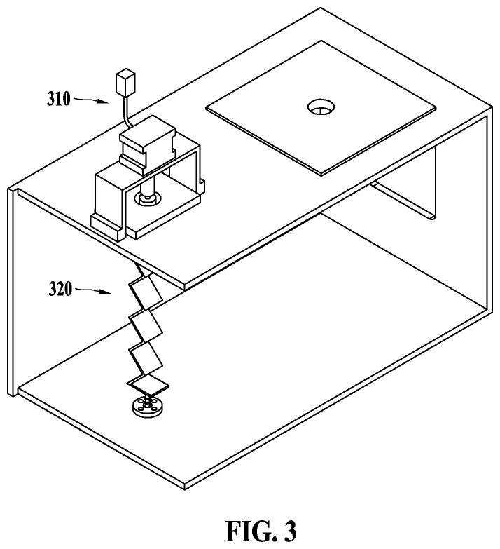

FIG. 3 is a three-dimensional structure diagram illustrating an electromagnetic reverberation chamber including a mode stirrer, according to an embodiment.

A rotation motor portion 310 may be installed on an outer upper portion of the electromagnetic reverberation chamber. The mode stirrer 320 may include a mode stirring panel configured to be rotated on a traverse section by a motor and a vertical movement portion configured to change the height of the mode stirring panel according to the rotating of the mode stirring panel and move the mode stirring panel up and down.

In addition, the mode stirring panel of the mode stirrer 320 may be rotated on the traverse section of the electromagnetic reverberation chamber with respect to a central axis by the rotation motor portion 310. Furthermore, the mode stirring panel of the mode stirrer 320 may move up and down by the vertical movement portion coupled to upper and lower portions of the mode stirrer 320, during the rotation. In other words, while the mode stirring panel of the mode stirrer 320 is rotated once by the rotation motor portion 310, the mode stirring panel of the mode stirrer 320 may perform a dynamic stirring function of moving downward and then returning to an original position.

The vertical movement portion may include a diagonal cut pipe in which an upper portion is coupled to the ceiling of the electromagnetic reverberation chamber and a lower portion is diagonally cut to form a cylindrical shape with different heights and a vertical column in which a lower portion is coupled to an upper portion of the mode stirring panel and an upper portion is in contact with the lower portion of the diagonal cut pipe, wherein the vertical column is configured to, when the mode stirring panel rotates, change the height of the mode stirring panel by moving up and down along a diagonal line formed at the lower portion of the diagonal cut pipe. In addition, the vertical movement portion may include a position restoration portion configured to be coupled between a lower portion of the mode stirring panel and a floor of the electromagnetic reverberation chamber, when the vertical column moves downward along the diagonal line formed at the upper portion of the diagonal cut pipe, contract by pressure being applied from the mode stirring panel that is coupled to the vertical column and moving downward, and when the vertical column moves upward along the diagonal line formed at the upper portion of the diagonal cut pipe and pressure from the mode stirring panel decreases, be tensioned and push the mode stirring panel upward.

In another embodiment, the vertical movement portion may include a diagonal cut pipe in which a lower portion is coupled to the floor of the electromagnetic reverberation chamber and an upper portion is diagonally cut to form a cylindrical shape with different heights and a vertical column in which an upper portion is coupled to a lower portion of the mode stirring panel and a lower portion is in contact with the upper portion of the diagonal cut pipe, wherein the vertical column is configured to, when the mode stirring panel rotates, change the height of the mode stirring panel by moving up and down along a diagonal line formed at the upper portion of the diagonal cut pipe. In addition, the vertical movement portion may include a position restoration portion configured to be coupled between an upper portion of the mode stirring panel and the ceiling of the electromagnetic reverberation chamber, when the vertical column moves upward along the diagonal line formed at the upper portion of the diagonal cut pipe, contract by pressure being applied from the mode stirring panel that is coupled to the vertical column and moving upward and downward, and when the vertical column moves downward along the diagonal line formed at the upper portion of the diagonal cut pipe and pressure from the mode stirring panel decreases, be tensioned and push the mode stirring panel downward. For example, the position restoration portion may be a spring.

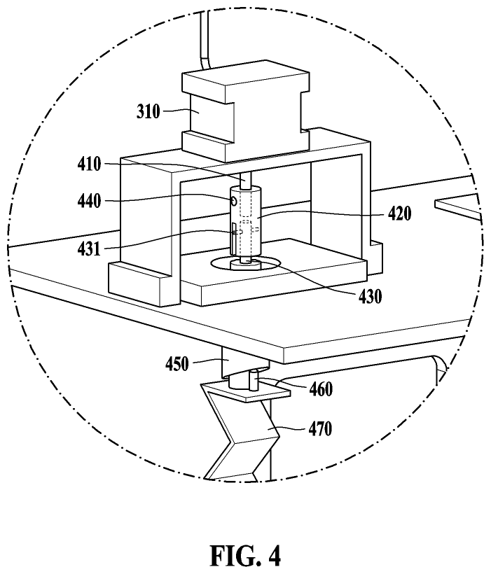

FIG. 4 is an enlarged view of an upper portion of a mode stirrer, according to an embodiment.

A motor central axis 410 of the rotation motor portion 310 may be a rotation axis of the rotation motor portion 310 or configured to be connected to the rotation axis of the rotation motor portion 310 and may be connected to a mode stirrer central axis separation support 420 through a screw hole 440.

The mode stirrer central axis separation support 420 may have an upper end coupled to the motor central axis 410 and a lower end with a groove formed so that a mode stirrer upper end central axis 430 may be inserted and coupled to the lower end. Here, a groove may be formed in a vertical axis on both sides of a lower portion of the mode stirrer central axis separation support 420 so that a T-shaped upper end of the inserted mode stirrer upper end central axis 430 may move up and down. In addition, the motor central axis 410 of the mode stirrer 320 and the mode stirrer upper end central axis 430 may not be engaged and may be separated within the mode stirrer central axis separation support 420.

An upper end 431 of the mode stirrer upper end central axis 430 may be formed in a T shape and may be inserted and coupled to the groove formed at the lower end of the mode stirrer central axis separation support 420.

Here, the mode stirrer upper end central axis 430 may not be directly coupled to the motor central axis 410 but may be spaced apart, as shown in FIG. 4. When the mode stirrer central axis separation support 420 rotates by rotation of the motor central axis 410, the mode stirrer upper end central axis 430 may also rotate by rotation of the upper end 431 coupled to the groove of the mode stirrer central axis separation support 420.

The mode stirrer upper end central axis 430 may penetrate a diagonal cut pipe 450 coupled to the ceiling of the electromagnetic reverberation room, and a lower end of the mode stirrer upper end central axis 430 may be coupled to an upper end of a mode stirring panel 470 of the mode stirrer 320.

The diagonal cut pipe 450 may have an upper portion coupled to the ceiling of the electromagnetic reverberation chamber and a lower portion diagonally cut to form a cylindrical shape with different heights

A vertical column 460 may have a lower end coupled to an upper portion of the mode stirring panel 470 at a position spaced from the center of the mode stirring panel 470 and an upper end in contact with the lower portion of the diagonal cut pipe 450. For example, the upper end of the vertical column 460 may be formed as a ball caster.

The mode stirring panel 470 may be manufactured in a zigzag shape, as shown in FIG. 4, or may be manufactured in another shape related to reverberation of electromagnetic waves.

When the rotation motor portion 310 rotates the motor central axis 410, the mode stirrer central axis separation support 420 connected to the motor central axis 410 may rotate. Accordingly, the mode stirrer upper end central axis 430 inserted and coupled to the lower portion of the mode stirrer central axis separation support 420 may rotate so that the mode stirring panel 470 coupled to a lower portion of the mode stirrer upper end central axis 430 may also rotate.

Here, the mode stirrer upper end central axis 430 may move up and down by the vertical column 460 engaged with the diagonal cut pipe 450. In addition, the upper end 431 of the mode stirrer upper end central axis 430 may move up and down through the groove formed in the vertical axis on both sides of the lower portion of the mode stirrer central axis separation support 420 and may transmit a rotational force of the mode stirrer central axis separation support 420 to a rotational force of the mode stirrer upper end central axis 430.

According to an embodiment, when the mode stirrer 320 rotates 180 degrees and moves to a lowest position, and again, when the mode stirrer 320 completes a 360-degree rotation from the 180-degree rotation, the apparatus may implement synchronization of moving upwards and positioning at an origin point.

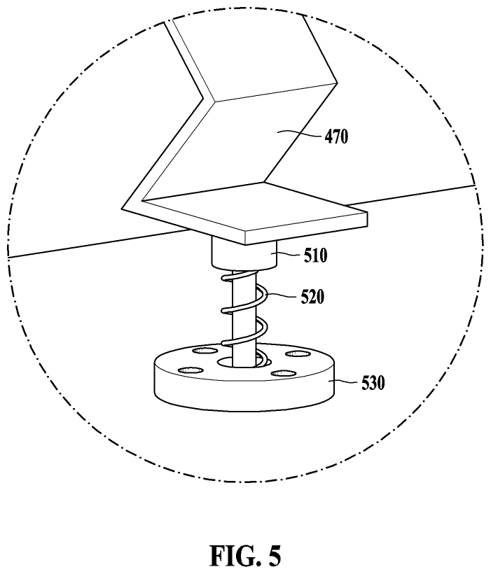

FIG. 5 is an enlarged view of a lower portion of a mode stirrer, according to an embodiment.

A mode stirrer lower end central axis 510 may be coupled to the lower portion of the mode stirring panel 470. In addition, a position restoration portion 520 may be coupled between the mode stirrer lower end central axis 510 and a spring support 530 installed on the floor of the electromagnetic reverberation chamber. For example, a spring is used in the position restoration portion 520, as shown in FIG. 5, but depending on embodiments, another configuration of contracting and tensioning according to pressure, such as a hydraulic cylinder or an air cylinder, may be used.

When the vertical column 460 moves downward along the diagonal line formed at the lower portion of the diagonal cut pipe 450, the position restoration portion 520 may be contracted by pressure being applied from the mode stirring panel 470 that is coupled to the vertical column 460 and moving downward. In addition, when the vertical column 460 moves upward along the diagonal line formed at the lower portion of the diagonal cut pipe 450 and the pressure from the mode stirring panel 470 decreases, the position restoration portion 520 may be tensioned and push the mode stirring panel 470 upward, thereby assisting the mode stirring panel 470 to move upward.

Furthermore, depending on embodiments, a spring may be arranged between the motor central axis 410 and the mode stirrer upper end central axis 430 instead of the position restoration portion 520. For example, when the position of the vertical column 460 that has moved to a lowest point along the diagonal line formed at the lower portion of the diagonal cut pipe 450 is a default position, a tension spring that pulls the motor central axis 410 and the mode stirrer upper end central axis 430 may be arranged between the motor central axis 410 and the mode stirrer upper end central axis 430 so that the vertical column 460 that has moved to the lowest point moves upward along the diagonal line formed at the lower portion of the diagonal cut pipe 450.

In addition, when the position of the vertical column 460 that has moved to a highest point of the diagonal line formed at the lower portion of the diagonal cut pipe 450 is a default position, a compression spring that pushes the motor central axis 410 and the mode stirrer upper end central axis 430 may be arranged between the motor central axis 410 and the mode stirrer upper end central axis 430 so that the vertical column 460 that has moved to the lowest point may move downward along the diagonal line formed at the lower portion of the diagonal cut pipe 450.

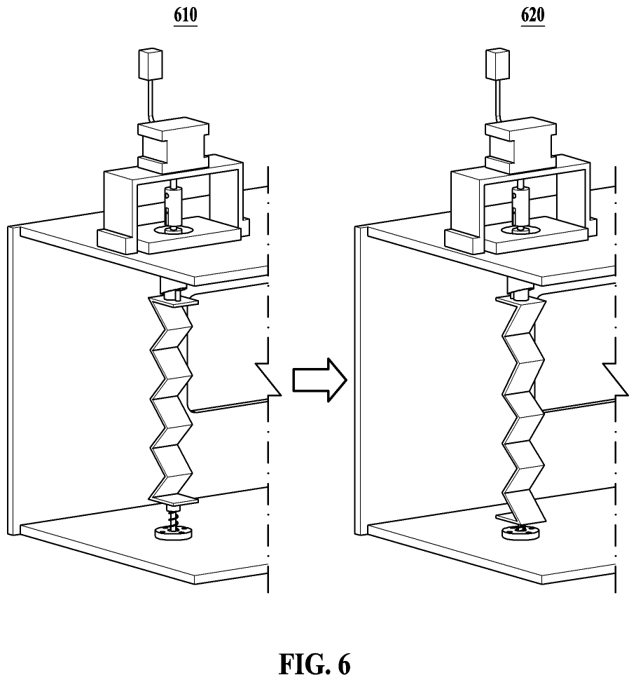

FIG. 6 illustrates an example of an operation of a mode stirrer, according to an embodiment.

The rotation motor portion 310 may rotate the motor central axis 410 and thus, may rotate the mode stirrer upper end central axis 430 and the mode stirring panel 470 coupled to the lower portion of the mode stirrer upper end central axis 430.

As shown in a diagram 610 of FIG. 6, when the vertical column 460 moves to a highest position from the lower end of the diagonal cut pipe 450 along the diagonal line formed at the lower portion of the diagonal cut pipe 450, the position restoration portion 520 may be tensioned and push the mode stirring panel 470 upward, thereby assisting the mode stirring panel 470 to move upward.

As shown in a diagram 620 of FIG. 6, when the vertical column 460 moves to a lowest position from the lower end of the diagonal cut pipe 450 along the diagonal line formed at the lower portion of the diagonal cut pipe 450, the mode stirring panel 470 may move downward by the vertical column 460. In addition, the position restoration portion 520 may be contracted by pressure being applied from the mode stirring panel 470.

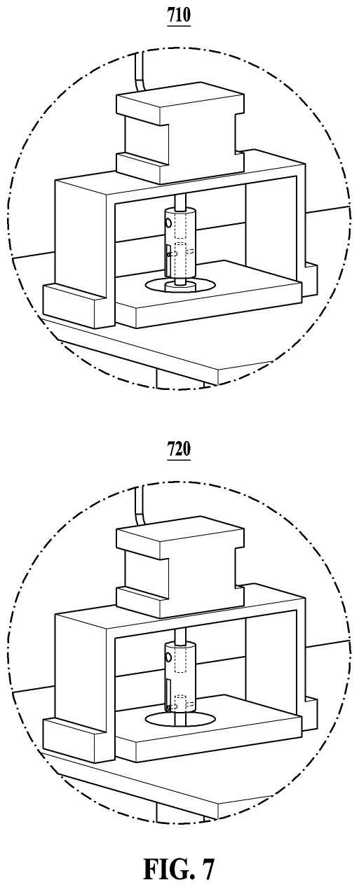

FIG. 7 illustrates an example of an operation of a mode stirrer upper end central axis according to an operation of the mode stirrer, according to an embodiment.

A diagram 710 of FIG. 7 is a diagram illustrating a state of the mode stirrer upper end central axis when the mode stirrer is in the state shown in the diagram 610 of FIG. 6, and a diagram 720 of FIG. 7 is a diagram illustrating a state of the mode stirrer upper end central axis when the mode stirrer is in the state shown in the diagram 620 of FIG. 6.

As shown in the diagram 610, when the vertical column 460 moves to a highest position from the lower end of the diagonal cut pipe 450 along the diagonal line formed at the lower portion of the diagonal cut pipe 450, the upper end 431 of the mode stirrer upper end central axis 430 may rise through the groove formed in the vertical axis on both sides of the lower portion of the mode stirrer central axis separation support 420, as shown in the diagram 710.

As shown in the diagram 620, when the vertical column 460 moves to a lowest position from the lower end of the diagonal cut pipe 450 along the diagonal line formed at the lower portion of the diagonal cut pipe 450, the upper end 431 of the mode stirrer upper end central axis 430 may be lowered through the groove formed in the vertical axis on both sides of the lower portion of the mode stirrer central axis separation support 420, as shown in the diagram 720.

The present disclosure provides an electromagnetic reverberation chamber with improved field uniformity performance by reducing measurement uncertainty in EMC measurement and OTA performance evaluation of a wireless terminal, by having a mode stirrer for performing up-and-down movement together with horizontal rotation.

The components described in the embodiments may be implemented by hardware components including, for example, at least one digital signal processor (DSP), a processor, a controller, an application-specific integrated circuit (ASIC), a programmable logic element, such as a field programmable gate array (FPGA), other electronic devices, or combinations thereof. At least some of the functions or the processes described in the embodiments may be implemented by software, and the software may be recorded on a recording medium. The components, the functions, and the processes described in the embodiments may be implemented by a combination of hardware and software.

Although the present specification includes details of a plurality of specific embodiments, the details should not be construed as limiting any invention or a scope that can be claimed, but rather should be construed as being descriptions of features that may be peculiar to specific embodiments of specific inventions. Specific features described in the present specification in the context of individual embodiments may be combined and implemented in a single embodiment. On the contrary, various features described in the context of a single embodiment may be implemented in a plurality of embodiments individually or in any appropriate sub-combination. Moreover, although features may be described above as acting in specific combinations and even initially claimed as such, one or more features from a claimed combination can in some cases be excised from the combination, and the claimed combination may be changed to a sub-combination or a modification of a sub-combination.

Likewise, although operations are depicted in a predetermined order in the drawings, it should not be construed that the operations need to be performed sequentially or in the predetermined order, which is illustrated to obtain a desirable result, or that all of the shown operations need to be performed. In specific cases, multitasking and parallel processing may be advantageous. In addition, it should not be construed that the separation of various device components of the aforementioned embodiments is required in all types of embodiments, and it should be understood that the described program components and devices are generally integrated as a single software product or packaged into a multiple-software product.

The embodiments disclosed in the present specification and the drawings are intended merely to present specific examples in order to aid in understanding of the present disclosure, but are not intended to limit the scope of the present disclosure. It will be apparent to one of ordinary skill in the art that various modifications based on the technical spirit of the present disclosure, as well as the disclosed embodiments, can be made.

What is claimed is:

1. A mode stirrer installed in an electromagnetic reverberation chamber, the mode stirrer comprising:
a mode stirring panel configured to be rotated on a traverse section by a motor; and
a vertical movement portion configured to change a height of the mode stirring panel according to the rotating of the mode stirring panel and move the mode stirring panel up and down.

2. The mode stirrer of claim 1, wherein
the vertical movement portion comprises:
a diagonal cut pipe in which an upper portion is coupled to a ceiling of the electromagnetic reverberation chamber and a lower portion is diagonally cut to form a cylindrical shape with different heights; and
a vertical column in which a lower portion is coupled to an upper portion of the mode stirring panel and an upper portion is in contact with the lower portion of the diagonal cut pipe,
wherein the vertical column is configured to, when the mode stirring panel rotates, change the height of the mode stirring panel by moving up and down along a diagonal line formed at the lower portion of the diagonal cut pipe.

3. The mode stirrer of claim 2, wherein
the vertical movement portion further comprises a position restoration portion configured to:
be coupled between a lower portion of the mode stirring panel and a floor of the electromagnetic reverberation chamber;
when the vertical column moves downward along the diagonal line formed at the lower portion of the diagonal cut pipe, contract by pressure being applied from the mode stirring panel that is coupled to the vertical column and moving downward; and
when the vertical column moves upward along the diagonal line formed at the lower portion of the diagonal cut pipe and pressure from the mode stirring panel decreases, be tensioned and push the mode stirring panel upward.

4. The mode stirrer of claim 1, wherein
the vertical movement portion comprises:
a diagonal cut pipe in which a lower portion is coupled to a floor of the electromagnetic reverberation chamber and an upper portion is diagonally cut to form a cylindrical shape with different heights; and
a vertical column in which an upper portion is coupled to a lower portion of the mode stirring panel and a lower portion is in contact with the upper portion of the diagonal cut pipe,
wherein the vertical column is configured to, when the mode stirring panel rotates, change the height of the mode stirring panel by moving up and down along a diagonal line formed at the upper portion of the diagonal cut pipe.

5. The mode stirrer of claim 4, wherein
the vertical movement portion further comprises a position restoration portion configured to:
be coupled between an upper portion of the mode stirring panel and a ceiling of the electromagnetic reverberation chamber;
when the vertical column moves upward along the diagonal line formed at the upper portion of the diagonal cut pipe, contract by pressure being applied from the mode stirring panel that is coupled to the vertical column and moving upward and downward; and
when the vertical column moves downward along the diagonal line formed at the upper portion of the diagonal cut pipe and pressure from the mode stirring panel decreases, be tensioned and push the mode stirring panel downward.

6. An electromagnetic reverberation chamber comprising:
a transmission antenna configured to output a wireless signal for measuring wireless performance;
a mode stirrer comprising a mode stirring panel;
a motor configured to rotate the mode stirring panel on a traverse section; and
a reception electric field probe configured to receive a reflection signal generated by a wireless signal output from the transmission antenna being reflected by the mode stirring panel,
wherein the mode stirrer comprises a vertical movement portion configured to change a height of the mode stirring panel according to the rotating of the mode stirring panel and move the mode stirring panel up and down.

7. The electromagnetic reverberation chamber of claim 6, wherein
the vertical movement portion comprises:
a diagonal cut pipe in which an upper portion is coupled to a ceiling of the electromagnetic reverberation chamber and a lower portion is diagonally cut to form a cylindrical shape with different heights; and
a vertical column in which a lower portion is coupled to an upper portion of the mode stirring panel and an upper portion is in contact with the lower portion of the diagonal cut pipe,
wherein the vertical column is configured to, when the mode stirring panel rotates, change the height of the mode stirring panel by moving up and down along a diagonal line formed at the lower portion of the diagonal cut pipe.

8. The electromagnetic reverberation chamber of claim 7, wherein
the vertical movement portion further comprises a position restoration portion configured to:
be coupled between a lower portion of the mode stirring panel and a floor of the electromagnetic reverberation chamber;
when the vertical column moves downward along the diagonal line formed at the lower portion of the diagonal cut pipe, contract by pressure being applied from the mode stirring panel that is coupled to the vertical column and moving downward; and
when the vertical column moves upward along the diagonal line formed at the lower portion of the diagonal cut pipe and pressure from the mode stirring panel decreases, be tensioned and push the mode stirring panel upward.

9. The electromagnetic reverberation chamber of claim 6, wherein
the vertical movement portion comprises:
a diagonal cut pipe in which a lower portion is coupled to a floor of the electromagnetic reverberation chamber and an upper portion is diagonally cut to form a cylindrical shape with different heights; and
a vertical column in which an upper portion is coupled to a lower portion of the mode stirring panel and a lower portion is in contact with the upper portion of the diagonal cut pipe,
wherein the vertical column is configured to, when the mode stirring panel rotates, change the height of the mode stirring panel by moving up and down along a diagonal line formed at the upper portion of the diagonal cut pipe.

10. The electromagnetic reverberation chamber of claim 9, wherein
the vertical movement portion further comprises a position restoration portion configured to:
be coupled between an upper portion of the mode stirring panel and a ceiling of the electromagnetic reverberation chamber;
when the vertical column moves upward along the diagonal line formed at the upper portion of the diagonal cut pipe, contract by pressure being applied from the mode stirring panel that is coupled to the vertical column and moving upward and downward; and
when the vertical column moves downward along the diagonal line formed at the upper portion of the diagonal cut pipe and pressure from the mode stirring panel decreases, be tensioned and push the mode stirring panel downward.
